(19) United States
(12) Patent Application Publication
(10) Pub. No.: US 2026/0261254 A1
(43) Pub. Date: Sep. 3, 2026

(54) ACOUSTIC RESONATOR

(71) Applicant: Huawei Technologies Co., Ltd., Shenzhen (CN)

(72) Inventors: Viktor Plesski, Helsinki (FI); Naiqing Zhang, Shanghai (CN)

(21) Appl. No.: 19/657,466

(22) Filed: Apr. 24, 2026

Related U.S. Application Data
(63) Continuation of application No. PCT/CN2023/137756, filed on Dec. 11, 2023.

(51) Int. Cl. H03H 9/17; H03H 9/02; H03H 9/05; H03H 9/56

(52) U.S. Cl. CPC H03H 9/174; H03H 9/02015; H03H 9/02157; H03H 9/02228; H03H 9/0504; H03H 9/568

(57) ABSTRACT

The present application relates to an acoustic resonator. An example acoustic resonator includes an interdigital transducer (IDT) formed on a multi-layered membrane that includes first and second piezoelectric layers and a dielectric layer therebetween. The dielectric layer is thermally conductive and non-piezoelectric. The IDT includes a set of interleaved fingers which is either provided on the second piezoelectric layer, or at least partly recessed into the multi-layered membrane on the side of the second piezoelectric layer. Each of a thickness of the first piezoelectric layer, a thickness of the second piezoelectric layer, and a thickness of the dielectric layer is defined by a layer-specific wavelength of a shear acoustic wave to be generated by the IDT in the multi-layered membrane at a resonant frequency of the acoustic resonator. Furthermore, the IDT has a pitch of at least twice a total thickness of the multi-layered membrane.

### CROSS-REFERENCE TO RELATED APPLICATIONS

This application is a continuation of International Application No. PCT/CN2023/137756, filed on Dec. 11, 2023, the disclosure of which is hereby incorporated by reference in its entirety.

### TECHNICAL FIELD

The present disclosure relates generally to the field of acoustic devices. In particular, the present disclosure relates to an acoustic resonator in which an interdigital transducer (IDT) is formed on a multi-layered membrane designed to improve heat evacuation capability, while providing high piezo-coupling.

### BACKGROUND

Acoustic resonators can be used to implement signal processing functions in various electronic applications. For example, the acoustic resonators are used in the existing wireless and wired communication devices, such as mobile phones, to implement radio frequency (RF) filters and/or multiplexers for transmitted and/or received wireless and/or wired signals. Some examples of the acoustic resonators include different types of surface acoustic wave (SAW) resonators, bulk acoustic wave (BAW) resonators, thin-film bulk acoustic resonators (FBARs), laterally excited bulk acoustic wave resonators (XBARs), transversally excited shear wave resonators (YBARs), stacked bulk acoustic resonators (SBARs), double bulk acoustic resonators (DBARs), and solidly mounted resonators (SMRs).

In the XBARs, a shear acoustic wave is excited by a lateral electric field between electrodes or fingers of an IDT formed on a suspended piezoelectric membrane typically made of lithium niobate (LN). The resonance frequency of such XBARs is mainly determined by the membrane thickness which, for fundamental-mode operation, corresponds to a half-wavelength, λ/2, of an acoustic wave resonating in the thickness direction of the membrane. In particular, the membrane thickness is about 400 nm for 5 GHz and less than 300 nm for 6 GHz and above. However, this submicron membrane is mechanically fragile, not to mention that the XBARs based thereon have poor power-handling properties due to the low thermal conductivity of LN and are difficult to fabricate as the bottom side of the membrane must be open. Furthermore, since LN has a high temperature coefficient of frequency (TCF) (of the order of −80 ppm/° C.), this results in significant resonance frequency shifts within the operational temperature range of the XBARs.

It has been recently proposed to use a three-layered piezoelectric membrane instead of the above-mentioned single-layered LN membrane in the XBARs. The three-layered piezoelectric membrane comprises top and bottom LN layers of the same orientation and a middle LN layer sandwiched therebetween and having an opposite orientation. Piezo-coupling in this three-layered piezoelectric membrane remains as strong as in the single-layered LN membrane, but the total thickness of the three-layered piezoelectric membrane is greater than that of the single-layered LN membrane, which makes it more mechanically robust. At the same time, the three-layered piezoelectric membrane still suffers from the same LN-related problems: its low thermal conductivity (which causes the heat generated mainly in the IDT electrodes to be mainly evacuated via the electrodes themselves to busbars first and then to a support substrate), and its high TCF (which results in significant resonance frequency shifts as an operational temperature changes). Moreover, it can be quite difficult to fabricate a membrane with different cuts or orientations of LN layers, as compared to a membrane with a single LN orientation.

Given the above, more engineering is required to improve the power-handling properties of the acoustic resonators, while remaining their piezo-coupling at a proper level.

### SUMMARY

This summary is provided to introduce a selection of concepts in a simplified form that are further described below in the detailed description. This summary is not intended to identify key features of the present disclosure, nor is it intended to be used to limit the scope of the present disclosure.

It is an objective of the present disclosure to provide an acoustic resonator that provides high piezo-coupling and exhibits improved (e.g., compared to the existing XBARs) power-handling properties at a resonant frequency.

The objective above is achieved by the features of the independent claims in the appended claims. Further embodiments and examples are apparent from the dependent claims, the detailed description, and the accompanying drawings.

According to an aspect, an acoustic resonator is provided. The acoustic resonator comprises a support substrate and a multi-layered membrane provided on the support substrate. The multi-layered membrane comprises a bottom piezoelectric layer, a top piezoelectric layer, and a dielectric layer sandwiched between the bottom piezoelectric layer and the top piezoelectric layer. The dielectric layer is thermally conductive and non-piezoelectric. The acoustic resonator further comprises an IDT comprising a set of interleaved fingers which is either provided on the top piezoelectric layer, or at least partly recessed into the multi-layered membrane starting from the top piezoelectric layer (or, in other words, on the side of the top piezoelectric layer). Each of the bottom piezoelectric layer, the top piezoelectric layer and the dielectric layer has a thickness defined based on a layer-specific wavelength/layer-specific of a shear acoustic wave to be generated by the IDT in the multi-layered membrane at a resonant frequency of the acoustic resonator. The thicknesses of the bottom piezoelectric layer, the top piezoelectric layer and the dielectric layer determine a total thickness of the multi-layered membrane. Furthermore, the IDT has a pitch of at least twice the total thickness of the multi-layered membrane. By using the dielectric layer (with a high thermal conductivity, e.g., at least 10 times higher than the thermal conductivity of LN) between the piezoelectric layers, it is possible to radically improve the power-handling properties of the acoustic resonator, while remaining its piezo-coupling strong. Moreover, the acoustic resonator thus configured exhibits a dramatically improved TCF (i.e., abs (TCF)<10 ppm/° C.) compared to the existing XBARs. Simultaneously, such a three-layered membrane is more robust than a single-layered membrane, especially for operation at a frequency higher than 5 GHz. Also, since such a three-layered membrane is symmetric in the thickness direction, it will not be bended due to different temperature extension coefficients of the piezoelectric and dielectric layers, as it might happen in case of two layers (e.g., LN/SiO2).

In one exemplary embodiment of the first aspect, the thickness of each of the bottom piezoelectric layer, the top piezoelectric layer and the dielectric layer is equal to about λ_{layer-specific}/2. By selecting the half-wavelength thickness of all the three layers, it is possible to provide their synchronous operation, which improves the operational performance of the acoustic resonator at the resonance frequency.

In one exemplary embodiment of the first aspect, the dielectric layer is made of one of SiO2, quartz, diamond, Si3N4 and AlN. These dielectric materials have high thermal conductivities, which may improve the power-handling properties of the acoustic resonator. It should be also noted that quartz can be considered as a dielectric non-piezoelectric material in this case, since the weak piezoelectric effect observed therein can be neglected compared to the strong piezoelectric effect observed in the top and bottom piezoelectric layers (e.g., made of LN).

In one exemplary embodiment of the first aspect, each of the top piezoelectric layer and the bottom piezoelectric layer is made of one of LN, lithium tantalate (LT), aluminum scandium nitride (AlScN), lithium iodate (LiIO3), zinc oxide (ZnO) and lead zirconate titanate (PZT). These materials exhibit proper piezoelectric properties for the efficient operation of the acoustic resonator.

In one exemplary embodiment of the first aspect, each of the top piezoelectric layer and the bottom piezoelectric layer is made of 128 Y-cut LN. Although any other LN cuts (e.g., a ZY-cut LN with a high e_{1,5} piezo-module value) may be used for the acoustic resonator, said 128 Y-cut LN may be more convenient to use due to its high commercial availability.

In one exemplary embodiment of the first aspect, the set of interleaved fingers is recessed into the multi-layered membrane such that each finger of the set of interleaved fingers extends through the top piezoelectric layer to either the dielectric layer or the bottom piezoelectric layer. By recessing the fingers into the multi-layered membrane, it is possible to provide better uniformity of electric fields in the multi-layered membrane, thereby providing higher piezo-coupling. Moreover, the direct contact of the fingers (which are heat sources) with the (thermally conductive) dielectric layer results in better heat evacuation through the dielectric layer towards the support substrate.

In one exemplary embodiment of the first aspect, the set of interleaved fingers is recessed into the multi-layered membrane, and each finger of the set of interleaved fingers is U-shaped. By using the U-shaped fingers, it is also possible to increase piezo-coupling in the acoustic resonator due to more free vibrations in the top piezoelectric layer of the multi-layered membrane.

In one exemplary embodiment of the first aspect, the acoustic resonator further comprises a set of pedestals spaced apart on the support substrate. Each pedestal of the set of pedestals is made of a thermally conductive material. In this embodiment, the multi-layered membrane is supported by the support substrate such that the set of pedestals is aligned with the set of interleaved fingers. By using such pedestals, it is possible to increase the mechanical robustness of the acoustic resonator, as well as to further improve heat evacuation from the multi-layered membrane (the heat may go through the pedestals to the support substrate). Furthermore, since the amplitude of vibrations goes to zero under the fingers of the IDT, the pedestals must be aligned with the fingers of the IDT to transfer minimal vibrations to the support substrate, thereby limiting losses of acoustic energy.

In one exemplary embodiment of the first aspect, each pedestal of the set of pedestals has a thickness equal to about

$$\frac{n * {λ}_{pedestal}}{4} ,$$

n=1, 3, 5, . . . , where λ_{pedestal} is a wavelength of the shear acoustic wave at the resonance frequency of the acoustic resonator in the material of the pedestal. The pedestals with such a thickness may additionally improve piezo-coupling in the acoustic resonator.

In one exemplary embodiment of the first aspect, each pedestal of the set of pedestals is made of a metal or dielectric material. These materials may improve the heat evacuation from the multi-layered membrane to the support substrate.

In one exemplary embodiment of the first aspect, the support substrate is made of one of SiC, diamond, BN, sapphire, and Si. The support substrate made of these materials is mechanically robust, non-conductive, and at the same time has a high thermal conductivity, thereby making the acoustic resonator less fragile and further improving its power-handling properties.

According to a second aspect, a RF filter is provided. The RF filter comprises a set of acoustic resonators each implemented as the acoustic resonator according to the first aspect. The set of acoustic resonators is arranged in a ladder scheme. The RF filter thus configured may be efficiently (especially for frequencies of more than 5 GHz) used for duplexers and multiplexers in user equipment (e.g., mobile phones, etc.) and network nodes (e.g., base stations, gNBs, etc.). By using the ladder scheme, it is possible to electrically connect the acoustic resonators both in series and in shunt branches of the “ladder” within the same RF filter. The ladder scheme also provides a close-packed arrangement of the acoustic resonators.

Other features and advantages of the present disclosure will be apparent upon reading the following detailed description and reviewing the accompanying drawings.

### BRIEF DESCRIPTION OF THE DRAWINGS

The present disclosure is explained below with reference to the accompanying drawings in which:

FIGS. 1A and 1B show different schematic views of an acoustic resonator according to one exemplary embodiment, namely: FIG. 1A shows a top view of the acoustic resonator, and

FIG. 1B shows a sectional side view of the acoustic resonator, as obtained by using section line A-A in FIG. 1A;

FIG. 2 schematically shows a magnified sectional side view of one period comprising two interleaved fingers of an interdigital transducer (IDT) included in the acoustic resonator according to a first exemplary embodiment, with the magnified sectional side view taken inside the area defined by rectangle B in FIG. 1B;

FIG. 3 schematically shows a shear acoustic wave excited in the multi-layered membrane included in the acoustic resonator;

FIG. 4 shows the absolute value of admittance Y11 on a logarithmic scale versus a frequency for the acoustic resonator comprising the multi-layered membrane of FIG. 2;

FIG. 5 shows how a resonance frequency and an antiresonance frequency shift in the abs(Y11)-on-frequency curve for the acoustic resonator comprising the multi-layered membrane of FIG. 2 as the operational temperature of the acoustic resonator increases by 115° C.;

FIG. 6 schematically shows a magnified sectional side view of one period comprising two interleaved fingers of the IDT included in the acoustic resonator according to a second exemplary embodiment, with the magnified sectional side view taken inside the area defined by rectangle B in FIG. 1B;

FIG. 7 schematically shows a magnified sectional side view of one period comprising two interleaved fingers of the IDT included in the acoustic resonator according to a third exemplary embodiment, with the magnified sectional side view taken inside the area defined by rectangle B in FIG. 1B;

FIG. 8 schematically shows a magnified sectional side view of one period comprising two interleaved fingers of the IDT included in the acoustic resonator according to a fourth exemplary embodiment, with the magnified sectional side view taken inside the area defined by rectangle B in FIG. 1B;

FIG. 9 schematically shows a magnified sectional side view of one period comprising two interleaved fingers of the IDT included in the acoustic resonator according to a fifth exemplary embodiment, with the magnified sectional side view taken inside the area defined by rectangle B in FIG. 1B;

FIG. 10 shows a schematic sectional side view of an acoustic resonator according to one other exemplary embodiment;

FIG. 11 shows the absolute value of admittance Y11 on a logarithmic scale versus a frequency for the acoustic resonator of FIG. 10;

FIG. 12 shows a schematic sectional side view of an acoustic resonator according to one other exemplary embodiment;

FIG. 13 shows the absolute value of admittance Y11 on a logarithmic scale versus a frequency for the acoustic resonator of FIG. 12; and

FIG. 14 shows a general block diagram of an RF filter according to one exemplary embodiment.

### DETAILED DESCRIPTION OF ILLUSTRATIVE EMBODIMENTS

Various embodiments of the present disclosure are further described in more detail with reference to the accompanying drawings. However, the present disclosure may be embodied in many other forms and should not be construed as limited to any certain structure or function discussed in the following description. In contrast, these embodiments are provided to make the description of the present disclosure detailed and complete.

According to the detailed description, it will be apparent to the ones skilled in the art that the scope of the present disclosure encompasses any embodiment thereof, which is disclosed herein, irrespective of whether this embodiment is implemented independently or in concert with any other embodiment of the present disclosure. For example, the apparatuses disclosed herein may be implemented in practice by using any numbers of the embodiments provided herein. Furthermore, it should be understood that any embodiment of the present disclosure may be implemented using one or more of the features presented in the appended claims.

The word “exemplary” is used herein in the meaning of “used as an illustration”. Unless otherwise stated, any embodiment described herein as “exemplary” should not be construed as preferable or having an advantage over other embodiments.

Any positioning terminology, such as “left”, “right”, “top”, “bottom”, “above” “below”, “upper”, “lower”, “horizontal”, “vertical”, etc., may be used herein for convenience to describe one element's or feature's relationship to one or more other elements or features in accordance with the figures. It should be apparent that the positioning terminology is intended to encompass different orientations of the apparatus disclosed herein, in addition to the orientation(s) depicted in the figures. As an example, if one imaginatively rotates the apparatus in the figures 90 degrees clockwise, elements or features described as “left” and “right” relative to other elements or features would then be oriented, respectively, “above” and “below” the other elements or features. Therefore, the positioning terminology used herein should not be construed as any limitation of the present disclosure.

Furthermore, although the numerative terminology, such as “first”, “second”, etc., may be used herein to describe various embodiments, elements or features, it should be understood that these embodiments, elements or features should not be limited by this numerative terminology. This numerative terminology is used herein only to distinguish one embodiment, element or feature from another embodiment, element or feature. For example, a first embodiment discussed below could be called a second embodiment, and vice versa, without departing from the teachings of the present disclosure.

The exemplary embodiments disclosed herein relate to an acoustic resonator that provides high piezo-coupling and exhibits improved (e.g., compared to the existing XBARs) power-handling properties at (and around) a resonant frequency. It should be noted that the term “piezo-coupling” refers herein to the whole acoustic resonator and corresponds to a relative Resonance-antiresonance (R-aR) value. More specifically, the acoustic resonator comprises an interdigital transducer (IDT) formed on a multi-layered membrane that comprises a bottom piezoelectric layer, a top piezoelectric layer, and a dielectric layer sandwiched between the bottom piezoelectric layer and the top piezoelectric layer. The dielectric layer is thermally conductive and non-piezoelectric. The IDT comprises a set of interleaved fingers which is either provided on the top piezoelectric layer, or at least partly recessed into the multi-layered membrane starting from the top piezoelectric layer (or, in other words, on the side of the top piezoelectric layer). Each of the bottom piezoelectric layer, the top piezoelectric layer and the dielectric layer has a thickness defined based on a layer-specific wavelength/layer-specific of a shear acoustic wave to be generated by the IDT in the multi-layered membrane at a resonant frequency of the acoustic resonator. Furthermore, the IDT has a pitch of at least twice the total thickness of the multi-layered membrane.

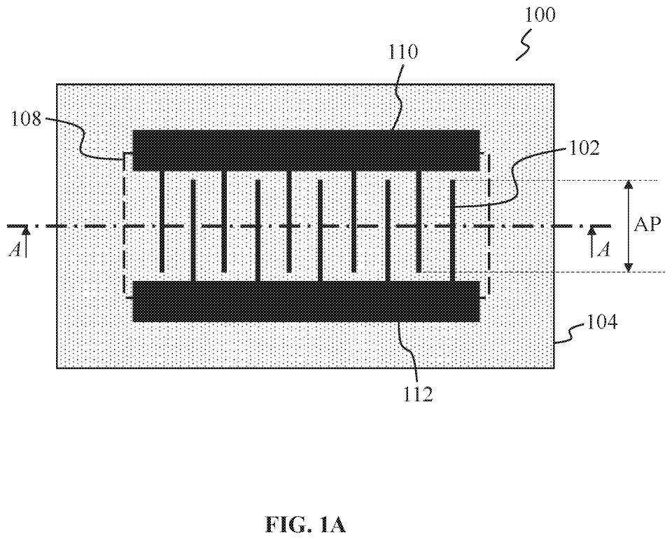

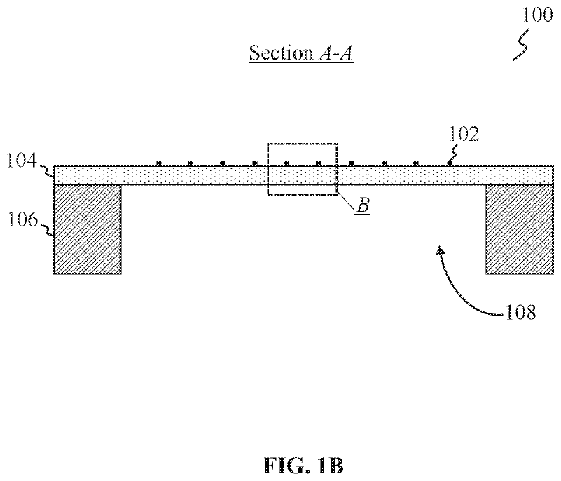

FIGS. 1A and 1B show different schematic views of an acoustic resonator 100 according to one exemplary embodiment. More specifically, FIG. 1A shows a top view of the acoustic resonator 100, and FIG. 1B shows a sectional side view of the acoustic resonator 100, as obtained by using section line A-A in FIG. 1A. The acoustic resonator 100 comprises an IDT comprising a set of interleaved fingers or electrodes 102 formed on a multi-layered membrane 104 comprising piezoelectric layers and a dielectric layer sandwiched therebetween, as will be discussed below in detail. The membrane 104 is provided on a support substrate 106 (see FIG. 1B). The support substrate 106 provides mechanical support to the membrane 104. Preferably, the support substrate 106 is made of any robust non-conductive material, such as SiC, diamond, BN, sapphire and Si. The membrane 104 may be bonded to the support substrate 106 using a wafer bonding process, or grown on the support substrate 106, or attached to the support substrate 106 in some other manner. Furthermore, the membrane 104 may be attached directly to the support substrate 106 or may be attached to the support substrate 106 via one or more intermediate layers.

As shown in FIGS. 1A and 1B, the support substrate 106 has a cavity 108 formed such that the middle part of the membrane 104 which comprises the IDT is suspended over the cavity 108 without contacting the support substrate 106. Although the cavity 108 is shown in FIG. 1B as a hole passing entirely through the support substrate 106, this should not be construed as any limitation of the present disclosure. In other embodiments, the cavity 108 may be implemented as a dead hole or recess. In general, the term “cavity” used herein should be understood as an empty space within a solid object. As also follows from FIG. 1B, the cavity 108 has a rectangular shape, but it is again worth noting that any other shape of the cavity 108, such as a regular or irregular polygon, is also possible, provided that the entire set of interleaved fingers 102 is suspended over it. The cavity 108 may be formed in the support substrate 106 either before or after the membrane 104 is attached to the support substrate 106. For this purpose, different techniques may be used, such as bulk micromachining, selective etching, etc. Furthermore, the support substrate 106 may comprise a top layer of a different material (e.g., a top SiO₂ layer), and the cavity 108 may be formed by deleting a part of this top layer under the IDT.

As shown in FIG. 1A, the set of interleaved fingers 102 comprises a first subset of fingers extending from a first (top) busbar 110 and a second subset of fingers extending from a second (bottom) busbar 112. Both subsets of fingers are interleaved. The interleaved fingers 102 overlap for a distance AP that is commonly referred to as the “aperture” of the IDT. The busbars 110 and 112 serve as two different-polarity terminals of the acoustic resonator 100. During operation, a radio frequency (RF) or microwave signal having a frequency comparable with the resonance frequency of the acoustic resonator 100 is applied to the busbars 110 and 112. As a result of the piezoelectric effect, a standing shear acoustic wave is excited within the membrane 104. For example, the shear acoustic wave has a mode that is mainly defined by the piezoelectric material of the membrane 104 (e.g., its cut with certain Euler angles).

It should be noted that the number, shape and arrangement of the constructive elements constituting the acoustic resonator 100, which are shown in FIGS. 1A and 1B, are not intended to be any limitation of the present disclosure, but merely used to provide a general idea of how the constructive elements may be implemented within the acoustic resonator 100. For example, the width of the cavity 108 in the direction of the interleaved fingers 102 of the IDT may correspond to the aperture AP, voids in LN may be made near the tips of the interleaved fingers 102, different types of reflectors may be implemented at the ends of the IDT, etc. Other well-known features used in the conventional XBARs to reduce the resistivity of fingers or electrodes and improve a Q-factor may be implemented in the acoustic resonator 100 by those skilled in the art.

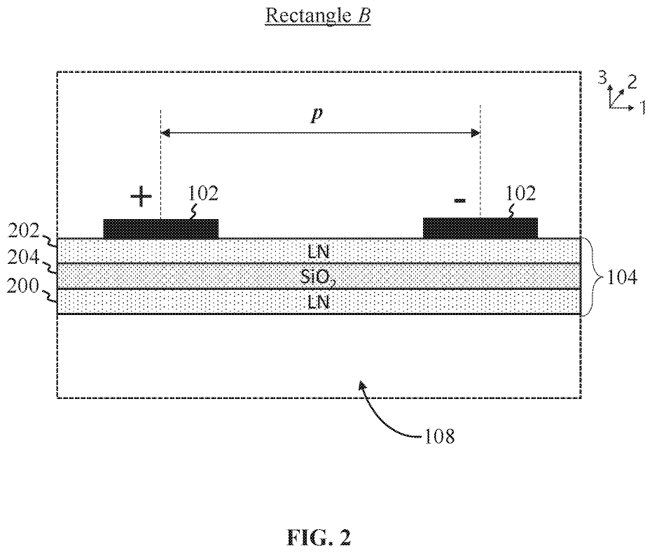

FIG. 2 shows a magnified sectional side view of one period comprising two interleaved fingers 102 of the IDT included in the acoustic resonator 100 according to a first exemplary embodiment. More specifically, this magnified sectional side view is taken inside the area defined by rectangle B in FIG. 1B. In FIG. 2, the left finger 102 is assumed to be connected to the busbar 110, and the right finger 102 is assumed to be connected to the busbar 112, with the busbars 110 and 112 serving as terminals which are fed with RF potentials of opposite polarity. It should be noted that the dimensions of the interleaved fingers 102 and the membrane 104 are not to scale in FIG. 2 for convenience—in practice, the thickness of the interleaved fingers 102 is usually smaller than the thickness of the membrane 104, while the width of the interleaved fingers 102 is at least comparable with the total thickness of the membrane 104. Also, the IDT has a pitch p which is at least twice the total thickness of the membrane 104.

As shown in FIG. 2, the membrane 104 is a three-layered structure that comprises a bottom piezoelectric layer 200, a top piezoelectric layer 202, and a dielectric layer 204 sandwiched between the piezoelectric layers 200 and 202. The set of interleaved fingers 102 is provided on the top piezoelectric layer 202 and may be made of any suitable metal, such Al, Cu, Au, etc., or any alloy of these and/or other metals. Each of the fingers 102 may also be configured as a multi-layered structure comprising different metal layers, such as Al/Cu/Ti, for example. Preferably, each of the piezoelectric layers 200 and 202 is made of LN (e.g., 128 Y-cut LN), and the dielectric layer 204 is made of SiO₂. However, other materials are also possible, such as quartz, diamond, Si₃N₄ and AlN for the dielectric layer 204 and lithium tantalate (LT), aluminum scandium nitride (AlScN), lithium iodate (LiIO3), zinc oxide (ZnO) and lead zirconate titanate (PZT) for each of the piezoelectric layers 200 and 202. It should be noted that the piezoelectric layers 200 and 202 may be made of different materials which preferably have similar piezoelectric properties (i.e., orientation or polarity). Each of the three layers constituting the membrane 104 is assumed to have a thickness that is selected based on the wavelength of the shear acoustic wave in that layer. It should be obvious to those skilled in the art that the shear acoustic wave generated by the IDT will propagate in the thickness direction of the membrane 104 and have a different wavelength in each of the three layers. Preferably, the piezoelectric layers 200 and 202 and the dielectric layer 204 all have a thickness of λ_{layer-specific}/2, where λ_{layer-specific} is the wavelength of the shear acoustic wave in a certain layer.

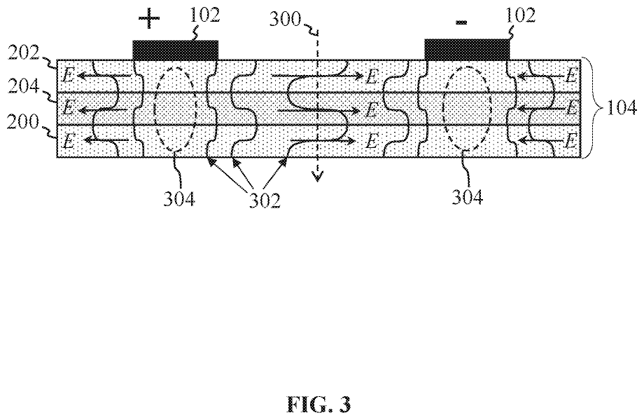

FIG. 3 schematically shows the shear acoustic wave excited in the multi-layered membrane 104 of the acoustic resonator 100. For simplicity, FIG. 3 again shows only two interleaved fingers 102 on the membrane 104 of the acoustic resonator 100, which is implemented in accordance with the first exemplary embodiment shown in FIG. 2. The RF potentials of periodically opposite polarity are fed to the interleaved fingers 102, thereby creating a time-varying electric field E between the fingers 102. The direction of the electric field E is mainly lateral due to the high dielectric permittivity of the piezoelectric layers and oppositely directed in the neighboring sections of the membrane 104, as indicated by the solid arrows labeled “E”. The direction of the electric field E shows that the acoustic resonator 100 is “laterally excited”, i.e., may function as an XBAR. The lateral electric field E causes shear deformations in the piezoelectric layers, resulting in the excitation of the shear acoustic wave in all layers of the membrane 104 in a direction 300. The shear deformations are shown in FIG. 3 by means of curves 302 illustrating the mechanical displacements in the shear acoustic wave. Basically, it is a standing shear wave resonance. As also follows from FIG. 3, there is substantially no horizontal electric field under the interleaved fingers 102 themselves, and the shear acoustic wave is only minimally excited in regions 304 under the interleaved fingers 102. Since acoustic vibrations are almost not excited under the interleaved fingers 102, the acoustic energy coupled to the interleaved fingers 102 is low (i.e., almost all the acoustic energy is retained in the membrane 104). This schematic illustration of the shear acoustic wave also shows that the interleaved fingers 102 are positioned in the nodes of the acoustic wave (i.e., in the points where the acoustic wave has a zero or minimum amplitude).

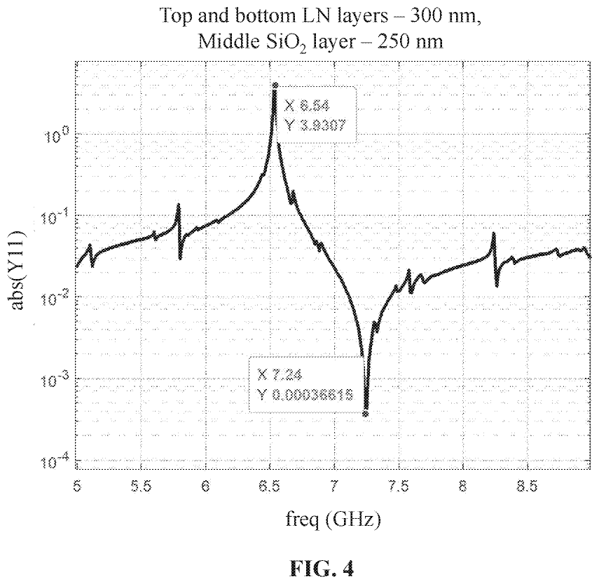

FIG. 4 shows the absolute value of admittance Y11 on a logarithmic scale versus a frequency for the acoustic resonator 100 comprising the multi-layered membrane 104 shown in FIG. 2. More specifically, the abs (Y11)-on-frequency curve is a FEM-simulated curve obtained for the multi-layered membrane 104 that comprises the top and bottom LN layers 200 and 202 each having a thickness of 300 nm and the middle SiO₂ layer 204 having a thickness of 250 nm. Furthermore, the IDT used comprises N=201 interleaved fingers 102. Since the thermal conductivity of SiO₂ is almost 2 orders higher than that of LN, the acoustic resonator 100 thus configured exhibits significantly improved (compared to the existing XBARs) power handling properties, while providing high piezo-coupling. No strong parasitic mode is observed in the abs (Y11)-on-frequency curve near the resonance and antiresonance frequencies.

The main simulated resonator parameters (i.e., R−aR=10.7%, which is a relative frequency difference between the resonance and antiresonance frequencies, and about 4 orders of magnitude of the impedance ratio at the antiresonance and resonance frequencies, with the resonance frequency being about 6.5 GHz) look good for many applications for filters of 5G phones and 6 GHz Wi-Fi.

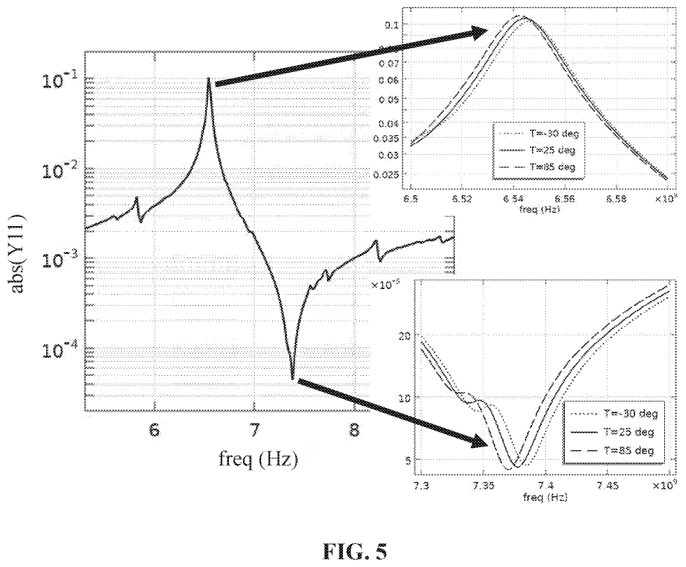

FIG. 5 shows how the resonance frequency and the antiresonance frequency shift in the abs (Y11)-on-frequency curve for the acoustic resonator 100 comprising the multi-layered membrane 104 of FIG. 2 as the operational temperature of the acoustic resonator 100 increases by 115° C. More specifically, the top insert in FIG. 5 corresponds to the temperature dependence of the resonance frequency, while the bottom insert in FIG. 5 corresponds to the temperature dependence of the antiresonance frequency. One can see that the presence of the middle SiO₂ layer 204 between the piezoelectric LN layers 200 and 202 can radically improve the TCF, i.e., abs (TCF)<10 ppm/° C., compared to about −80 ppm/° C. for a single-layered LN membrane used in the conventional XBARs.

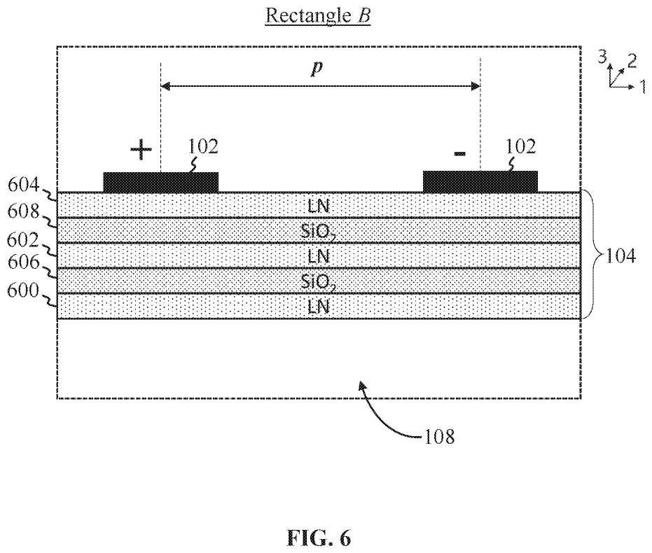

FIG. 6 shows a magnified sectional side view of one period comprising two interleaved fingers 102 of the IDT included in the acoustic resonator 100 according to a second exemplary embodiment. Again, this magnified sectional side view is taken inside the area defined by rectangle B in FIG. 1B. In FIG. 6, the left finger 102 is assumed to be connected to the busbar 110, and the right finger 102 is assumed to be connected to the busbar 112, with the busbars 110 and 112 serving as terminals which are fed with alternating (with opposite polarity) RF potentials. It should be noted that the dimensions of the interleaved fingers 102 and the membrane 104 are shown not to scale in FIG. 6 for convenience.

In the second exemplary embodiment, the membrane 104 is a five-layered structure that comprises three piezoelectric layers 600, 602, and 604 and two dielectric layers 606 and 608. Preferably, each of the layers 600-608 has a thickness of λ_{layer-specific}/2. Each of the dielectric layers 606 and 608 is sandwiched between corresponding two of the piezoelectric layers 600, 602, and 604. The set of interleaved fingers 102 is provided on the top piezoelectric layer 604 and may be made of any suitable metal or metal alloy. The piezoelectric layers 600, 602, and 604 may be configured in the same or similar manner as the piezoelectric layers 200 and 202, and have identical polarization, while the dielectric layers 606 and 608 may be configured in the same or similar manner as the dielectric layer 204. The five-layered membrane 104 shown in FIG. 6 results in the excitation of a similar shear acoustic wave (close to a A5 mode) as the one shown in FIG. 3. It should be noted that the present disclosure is not limited to the three-layered and five-layered structures of the membrane 104 shown in FIGS. 2 and 6, respectively—in the general case, the membrane 104 may comprise n piezoelectric and dielectric layers in an alternating sequence, where n=2, 3,4, . . . , with uneven numbers being preferred to avoid temperature bending of the asymmetric membrane for n=2, 4, . . . .

It is clear to a person skilled in the art that the structure can include 7 or more layers. Also, any dielectric layer may be replaced by a piezoelectric layer of inverted polarity, thus increasing the piezo-coupling, but decreasing the power handling capability and, vice versa, as well as any piezoelectric layer can be replaced by a dielectric layer (increasing the power handling capability, but deceasing the piezo-coupling).

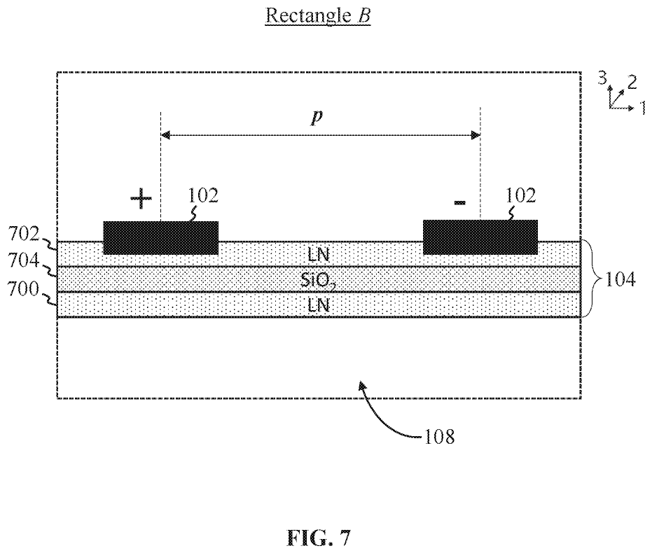

FIG. 7 shows a magnified sectional side view of one period comprising two interleaved fingers 102 of the IDT included in the acoustic resonator 100 according to a third exemplary embodiment. Again, this magnified sectional side view is taken inside the area defined by rectangle B in FIG. 1B. In FIG. 7, the left finger 102 is assumed to be connected to the busbar 110, and the right finger 102 is assumed to be connected to the busbar 112, with the busbars 110 and 112 serving as terminals which are fed with alternating (with opposite polarity) RF potentials. It should be noted that the dimensions of the interleaved fingers 102 and the membrane 104 are not to scale in FIG. 7 for convenience.

In the third exemplary embodiment, the membrane 104 is configured in the same manner as in the first exemplary embodiment and comprises a bottom piezoelectric layer 700, a top piezoelectric layer 702, and a dielectric layer 704 sandwiched between the piezoelectric layers 700 and 702. Correspondingly, the piezoelectric layers 700 and 702 may be configured in the same or similar manner as the piezoelectric layers 200 and 202, while the dielectric layer 704 may be configured in the same or similar manner as the dielectric layer 204. At the same time, the third exemplary embodiment is characterized by that the (metal) fingers 102 are partly recessed into the top piezoelectric layer 702 of the membrane 104. It should be noted that the same recessed fingers 102 may be implemented in the second exemplary embodiment, i.e., the recessed fingers 102 shown in FIG. 7 may be used in the five-layered membrane 104 shown in FIG. 6, for example. Such recessed fingers 102 may create a more uniform electric field in the piezoelectric layers, resulting in an increased R-aR relative frequency gap, and may have more contact with the constituent layers of the membrane 104 for better heat evacuation, thus increasing the power handling capability of the acoustic resonator 100.

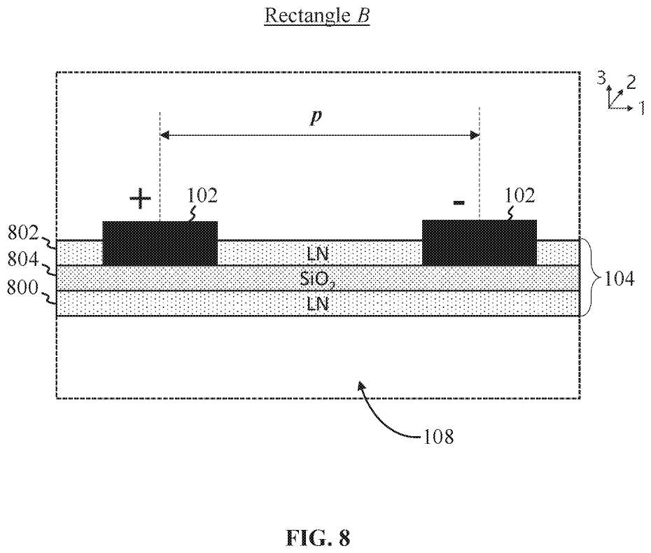

FIG. 8 shows a magnified sectional side view of one period comprising two interleaved fingers 102 of the IDT included in the acoustic resonator 100 according to a fourth exemplary embodiment. Again, this magnified sectional side view is taken inside the area defined by rectangle B in FIG. 1B. In FIG. 8, the left finger 102 is assumed to be connected to the busbar 110, and the right finger 102 is assumed to be connected to the busbar 112, with the busbars 110 and 112 serving as terminals which are fed with alternative (with opposite polarity) RF potentials. It should be noted that the dimensions of the interleaved fingers 102 and the membrane 104 are not to scale in FIG. 8 for convenience.

In the fourth exemplary embodiment, the membrane 104 is configured in the same manner as in the first exemplary embodiment and comprises a bottom piezoelectric layer 800, a top piezoelectric layer 802, and a dielectric layer 804 sandwiched between the piezoelectric layers 800 and 802. Correspondingly, the piezoelectric layers 800 and 802 may be configured in the same or similar manner as the piezoelectric layers 200 and 202, while the dielectric layer 804 may be configured in the same or similar manner as the dielectric layer 204. At the same time, the fourth exemplary embodiment is characterized by that the (metal) fingers 102 extend through the top piezoelectric layer 802 of the membrane 104 to the dielectric layer 804 of the membrane 104. It should be again noted that the same recessed fingers 102 may be implemented in the second exemplary embodiment, i.e., the recessed fingers 102 shown in FIG. 8 may be used in the five-layered membrane 104 shown in FIG. 6, for example. The contact between the fingers 102 and the dielectric layer 804 results in the improved evacuation of the heat created in the fingers 102 through the dielectric layer 804 (with a high thermal conductivity) to the support substrate 106 and, thus, improves the power handling properties of the acoustic resonator 100. Furthermore, the recessed fingers 102 may create a more uniform electric field in the top piezoelectric layer 802, which increases piezo-coupling.

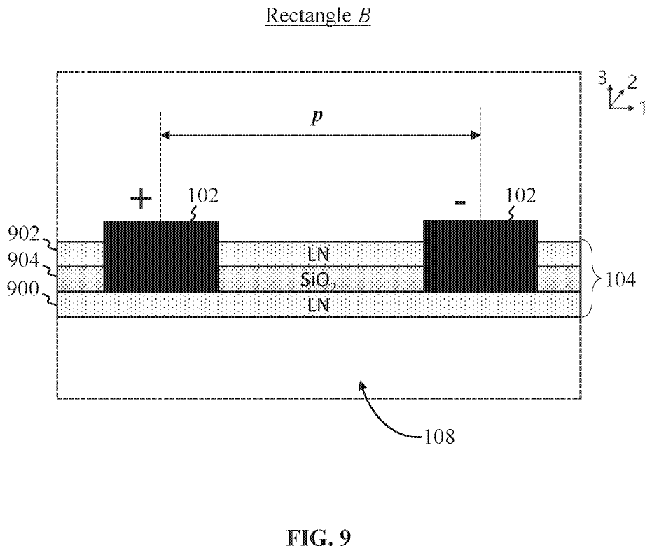

FIG. 9 shows a magnified sectional side view of one period comprising two interleaved fingers 102 of the IDT included in the acoustic resonator 100 according to a fifth exemplary embodiment. Again, this magnified sectional side view is taken inside the area defined by rectangle B in FIG. 1B. In FIG. 9, the left finger 102 is assumed to be connected to the busbar 110, and the right finger 102 is assumed to be connected to the busbar 112, with the busbars 110 and 112 serving as terminals which are fed with alternating (with opposite polarity) RF potentials. It should be noted that the dimensions of the interleaved fingers 102 and the membrane 104 are not to scale in FIG. 9 for convenience.

In the fifth exemplary embodiment, the membrane 104 is configured in the same manner as in the first exemplary embodiment and comprises a bottom piezoelectric layer 900, a top piezoelectric layer 902, and a dielectric layer 904 sandwiched between the piezoelectric layers 900 and 902. Correspondingly, the piezoelectric layers 900 and 902 may be configured in the same or similar manner as the piezoelectric layers 200 and 202, while the dielectric layer 904 may be configured in the same or similar manner as the dielectric layer 204. At the same time, the fifth exemplary embodiment is characterized by that the (metal) fingers 102 extend through the top piezoelectric layer 902 and the dielectric layer 904 of the membrane 104 to the bottom piezoelectric layer 900 of the membrane 104. It should be again noted that the same recessed fingers 102 may be implemented in the second exemplary embodiment, i.e., the recessed fingers 102 shown in FIG. 9 may be used in the five-layered membrane 104 shown in FIG. 6, for example. Again, the recessed fingers 102 shown in FIG. 9 provide the same advantages as those shown in FIG. 8. Additionally, the recessed fingers 102 shown in FIG. 9 provide a more uniform/strong electric field in the bottom piezoelectric layer 900, resulting in a bit higher piezo-coupling. Also, since the recessed fingers 102 shown in FIG. 9 are thick enough, they have a lower (e.g., compared to those shown in FIG. 8) electric resistivity and provide a better thermal conductivity.

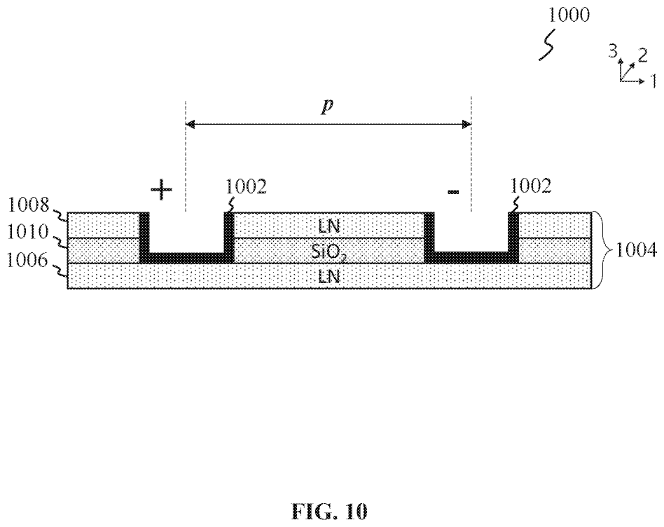

FIG. 10 shows a schematic sectional side view of an acoustic resonator 1000 according to one other exemplary embodiment. More specifically, FIG. 10 shows a magnified sectional side view of one period comprising two interleaved fingers 1002 of an IDT included in the acoustic resonator 1000. Unlike the above-described fingers 102, the fingers 1002 are shown to be fully recessed or embedded into a multi-layered membrane 1004 that comprises a bottom piezoelectric layer 1006, a top piezoelectric layer 1008, and a dielectric layer 1010 sandwiched between the piezoelectric layers 1006 and 1008. The piezoelectric layers 1006 and 1008 may be configured in the same or similar manner as the piezoelectric layers 200 and 202, while the dielectric layer 1010 may be configured in the same or similar manner as the dielectric layer 204. The fingers 1002 are also characterized by that they are U-shaped. It should be noted that the depth of the U-shaped fingers 1002 may be arbitrary. For example, the depth of the U-shaped fingers 1002 may be equal to the thickness of the top piezoelectric layer 1008, so that they extend through the top piezoelectric layer 1008 to the dielectric layer 1010 only, or their depth may be even smaller than the thickness of the top piezoelectric layer 1008. Furthermore, the U-shaped fingers 1002 may unnecessarily be made flush with the upper surface of the top piezoelectric layer 1008—i.e., they may be partly (not fully) recessed into the membrane 1004, if required and depending on particular applications. The operational principle of the acoustic resonator 1000 is similar to that of the acoustic resonator 100. It is also worth noting that the U-shaped fingers 1002 may be implemented in the five-layered membrane 104 shown in FIG. 6. The top piezoelectric layer 1008 can vibrate more freely with a larger amplitude of vibrations near the ends of the piezoelectric layer 1008 (not going to zero, as shown in FIG. 3) and that provides a higher energy accumulated in the acoustic resonator 1000 and that improves piezo-coupling.

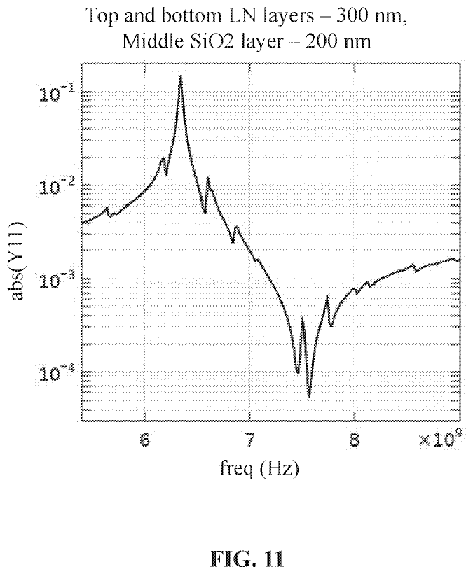

FIG. 11 shows the absolute value of admittance Y11 on a logarithmic scale versus a frequency for the acoustic resonator 1000. This is the result of the FEM simulation of an infinite periodic structure. The parasitic mode observed near the antiresonance frequency is more pronounced in periodic structures. It can be less important in a finite resonator and further suppressed by the correct choice of the pitch and the dielectric layer thickness. The simulation curve shows highly increased piezo-coupling, i.e., R−aR=17.6%, and the impedance ration between the anti-resonance and resonance frequencies is of about 4 orders. Such parameters are suitable for many applications for filters of 5G phones and 6 GHz Wi-Fi.

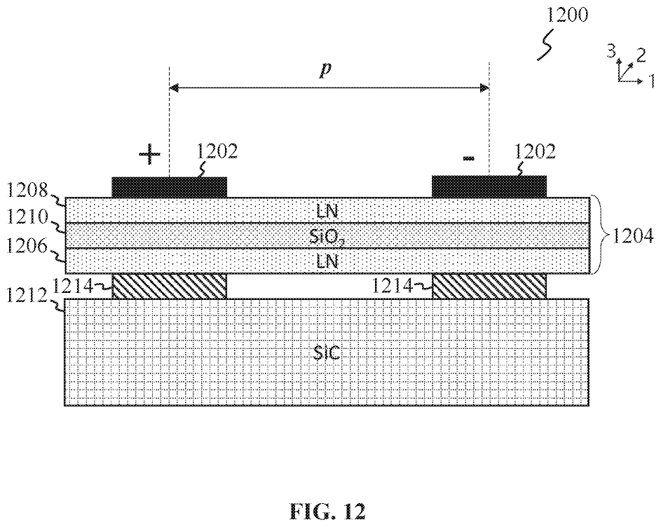

FIG. 12 shows a schematic sectional side view of an acoustic resonator 1200 according to one other exemplary embodiment. More specifically, FIG. 12 shows a magnified sectional side view of one period comprising two interleaved fingers 1202 of an IDT included in the acoustic resonator 1200. In the acoustic resonator 1200, the IDT is formed on a multi-layered membrane 1204 which may be implemented in the same or similar manner as the membrane 104 shown in FIG. 2. In other words, the membrane 1204 comprises a bottom piezoelectric layer 1206, a top piezoelectric layer 1208, and a dielectric layer 1210 sandwiched between the piezoelectric layers 1206 and 1208. The set of interleaved fingers 1202 is provided on the top piezoelectric layer 1208 and may be made of any suitable metal or metal alloy.

Unlike the acoustic resonators 100 and 1000, the acoustic resonator 1200 further comprises a support substrate 1212 and a set of pedestals 1214 provided thereon. The set of pedestals 1214 is aligned with the set of interleaved fingers 1202. The pedestals 1214 may be made of any thermally conductive material, such a metal or dielectric material (e.g., Al or SiO₂). In one embodiment, the pedestals 1214 may be formed by depositing one or more layers of thermally conductive material on the substrate 1212 and then partly removing (e.g., using any suitable lithography techniques, such as photolithography) such layer(s) at regular intervals (so that the resulting pedestals 1214 are under and aligned with the interleaved fingers 1202). In another embodiment, the pedestals 1214 may be formed by creating (e.g., etching) cavities in the substrate 1212 at regular intervals (so that the resulting pedestals 1214 defined by the walls of such cavities are under and aligned with the interleaved fingers 1202); in this embodiment, the pedestals 1214 may be made of the substrate material. Furthermore, the pedestals 1214 may be shaped in the same or similar manner as the fingers 1202, or they may be shaped differently compared to the fingers 1202 (e.g., the pedestals 1214 may have a mushroom-like shape, so that a set of pedestals is arranged under and along each finger 1202). The support substrate 1212 may be made of the same material as the support substrate 106 (i.e., SiC, diamond, BN, sapphire, or Si). The pedestals 1214 is assumed to have a thickness which is also defined by the wavelength of the shear acoustic wave generated by the IDT. Preferably, the pedestals 1214 have a thickness of about

$$\frac{n * {λ}_{pedestal}}{4} ,$$

n=1, 3, 5, . . . , where λ_{pedestal} is the wavelength of the shear acoustic wave at the resonance frequency of the acoustic resonator 1200 in the material of the pedestal 1214. The operational principle of the acoustic resonator 1200 is similar to that of the acoustic resonator 100. It should be noted that the pedestals 1214 may be implemented not only in combination with the three-layered membrane 1204, but also in combination with the five-layered membrane 104 shown in FIG. 6 and the partly or fully recessed fingers 102 and 1002 shown in any of FIGS. 7-10.

By using the pedestals 1214, one may make the acoustic resonator structure more robust mechanically and further improve the heat evacuation directly through the pedestals to the support substrate 1212. The metal pedestals 1214 may be electrically connected to the corresponding opposite fingers 1202 and corresponding busbars, thus reducing electric resistivity (and ohmic heating) and making the electric field more uniform in both piezoelectric layers 1206 and 1208.

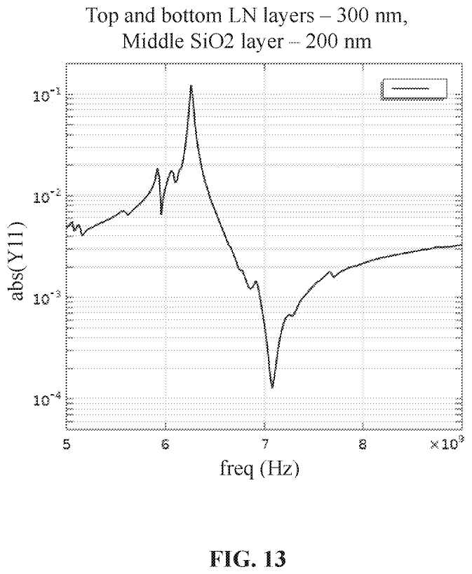

FIG. 13 shows the absolute value of admittance Y11 on a logarithmic scale versus a frequency for the acoustic resonator 1200. One can see that no strong parasitic mode is observed near the resonance and antiresonance frequencies in this particular geometry of the resonator. The improved power-handling properties of the acoustic resonator 1200 are expected because direct heat evacuation through the pedestals 1214 to the support substrate 1212 downwards. This FEM simulation shows slightly reduced piezo-coupling, i.e., R−aR=10.0%, (or 12.3% for the case when the pedestals 1214 are used as an additional IDT), and about 3 orders of magnitude of the impedance ration between the anti-resonance and resonance frequencies. Such parameters are suitable for many applications for filters of 5G phones and 6 GHz Wi-Fi.

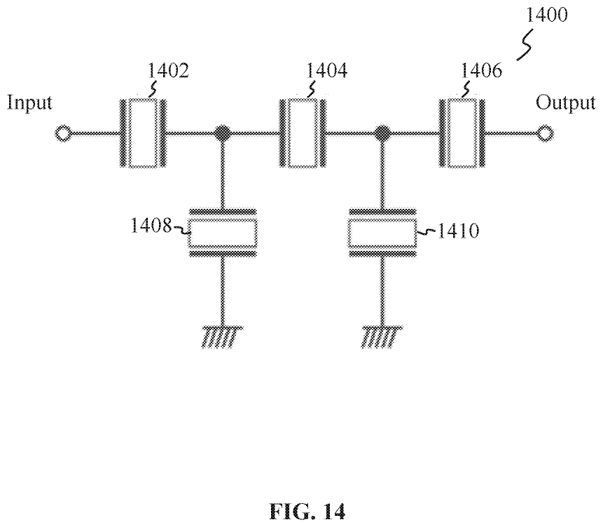

FIG. 14 shows a general block diagram of an RF filter 1400 according to one exemplary embodiment. The RF filter 1400 comprises a set of acoustic resonators 1402, 1404, 1406, 1408, and 1410, which are arranged in a ladder scheme. Each of the acoustic resonators 1402, 1404, 1406, 1408, and 1410 may be implemented as any of the acoustic resonators 100, 1000, and 1200. For example, each of the acoustic resonators 1402, 1404, 1406 may be implemented as the acoustic resonator 100 comprising the membrane 104 shown in FIG. 2, while each of the acoustic resonators 1408 and 1410 may be implemented as the acoustic resonator 1000. In general, any combination of the acoustic resonators discussed above is possible within the RF filter 1400. Furthermore, depending on desired filter performance, the “ladder” RF filter 1400 may include even more acoustic resonators, e.g., 7 to 10. The frequency shift between the series and parallel (shunt) acoustic resonators can be achieved using a different pitch, or by adjusting the thickness of the top piezoelectric layer in each acoustic resonator.

Although the exemplary embodiments of the present disclosure are described herein, it should be noted that any various changes and modifications could be made in the embodiments of the present disclosure, without departing from the scope of legal protection which is defined by the appended claims. In the appended claims, the word “comprising” does not exclude other elements or operations, and the indefinite article “a” or “an” does not exclude a plurality. The mere fact that certain measures are recited in mutually different dependent claims does not indicate that a combination of these measures cannot be used to advantage.

What is claimed is:

1. An acoustic resonator comprising:
a support substrate;
a multi-layered membrane provided on the support substrate and comprising:
a first piezoelectric layer;
a second piezoelectric layer; and
a dielectric layer between the first piezoelectric layer and the second piezoelectric layer, the dielectric layer being thermally conductive and non-piezoelectric; and
an interdigital transducer (IDT) comprising a set of interleaved fingers;
wherein the set of interleaved fingers is either provided on the second piezoelectric layer, or at least partly recessed into the multi-layered membrane starting from the second piezoelectric layer;
wherein each of a thickness of the first piezoelectric layer, a thickness of the second piezoelectric layer, and a thickness of the dielectric layer is defined based on a layer-specific wavelength λ_{layer-specific} of a shear acoustic wave to be generated by the IDT in the multi-layered membrane at a resonant frequency of the acoustic resonator, the thickness of the first piezoelectric layer, the thickness of the second piezoelectric layer, and the thickness of the dielectric layer determining a total thickness of the multi-layered membrane; and
wherein the IDT has a pitch of at least twice the total thickness of the multi-layered membrane.

2. The acoustic resonator of claim 1, wherein each of the thickness of the first piezoelectric layer, the thickness of the second piezoelectric layer, and the thickness of the dielectric layer is equal to
$$\frac{{λ}_{layer - specific}}{2} .$$

3. The acoustic resonator of claim 1, wherein the dielectric layer comprises one of SiO₂, quartz, diamond, Si₃N₄ and AlN.

4. The acoustic resonator of claim 1, wherein each of the second piezoelectric layer and the first piezoelectric layer comprises one of lithium niobate (LN), lithium tantalate (LT), aluminum scandium nitride (AlScN), lithium iodate (LiIO₃), zinc oxide (ZnO) and lead zirconate titanate (PZT).

5. The acoustic resonator of claim 4, wherein each of the second piezoelectric layer and the first piezoelectric layer comprises 128 Y-cut LN.

6. The acoustic resonator of claim 1, wherein the set of interleaved fingers is recessed into the multi-layered membrane such that each finger of the set of interleaved fingers extends through the second piezoelectric layer to either the dielectric layer or the first piezoelectric layer.

7. The acoustic resonator of claim 1, wherein the set of interleaved fingers is recessed into the multi-layered membrane, and each finger of the set of interleaved fingers is U-shaped.

8. The acoustic resonator of claim 1, further comprising:
a set of pedestals spaced apart on the support substrate, each pedestal of the set of pedestals comprising a thermally conductive material;
wherein the multi-layered membrane is supported by the support substrate such that the set of pedestals is aligned with the set of interleaved fingers.

9. The acoustic resonator of claim 8, wherein each pedestal of the set of pedestals has a thickness equal to about
$$\frac{n * {λ}_{pedestal}}{4} ,$$
n=1, 3, 5, . . . , wherein λ_{pedestal} is a wavelength of the shear acoustic wave at the resonance frequency of the acoustic resonator in the thermally conductive material of each pedestal.

10. The acoustic resonator of claim 8, wherein each pedestal of the set of pedestals comprises a metal or dielectric material.

11. The acoustic resonator of claim 1, wherein the support substrate comprises one of SiC, diamond, BN, sapphire, and Si.

12. A radio frequency (RF) filter comprising a set of acoustic resonators, wherein the set of acoustic resonators is arranged in a ladder scheme, each acoustic resonator comprising:
a support substrate;
a multi-layered membrane provided on the support substrate and comprising:
a first piezoelectric layer;
a second piezoelectric layer; and
a dielectric layer between the first piezoelectric layer and the second piezoelectric layer, the dielectric layer being thermally conductive and non-piezoelectric; and
an interdigital transducer (IDT) comprising a set of interleaved fingers;
wherein the set of interleaved fingers is either provided on the second piezoelectric layer, or at least partly recessed into the multi-layered membrane starting from the second piezoelectric layer;
wherein each of a thickness of the first piezoelectric layer, a thickness of the second piezoelectric layer, and a thickness of the dielectric layer is defined based on a layer-specific wavelength λ_{layer-specific} of a shear acoustic wave to be generated by the IDT in the multi-layered membrane at a resonant frequency of the acoustic resonator, the thickness of the first piezoelectric layer, the thickness of the second piezoelectric layer, and the thickness of the dielectric layer determining a total thickness of the multi-layered membrane; and
wherein the IDT has a pitch of at least twice the total thickness of the multi-layered membrane.

13. The RF filter of claim 12, wherein each of the thickness of the first piezoelectric layer, the thickness of the second piezoelectric layer, and the thickness of the dielectric layer is equal to
$$\frac{{λ}_{layer - specific}}{2} .$$

14. The RF filter of claim 12, wherein the dielectric layer comprises one of SiO₂, quartz, diamond, Si₃N₄ and AlN.

15. The RF filter of claim 12, wherein each of the second piezoelectric layer and the first piezoelectric layer comprises one of lithium niobate (LN), lithium tantalate (LT), aluminum scandium nitride (AlScN), lithium iodate (LiIO₃), zinc oxide (ZnO) and lead zirconate titanate (PZT).

16. The RF filter of claim 15, wherein each of the second piezoelectric layer and the first piezoelectric layer comprises 128 Y-cut LN.

17. The RF filter of claim 12, wherein the set of interleaved fingers is recessed into the multi-layered membrane such that each finger of the set of interleaved fingers extends through the second piezoelectric layer to either the dielectric layer or the first piezoelectric layer.

18. The RF filter of claim 12, wherein the set of interleaved fingers is recessed into the multi-layered membrane, and each finger of the set of interleaved fingers is U-shaped.

19. The RF filter of claim 12, further comprising:
a set of pedestals spaced apart on the support substrate, each pedestal of the set of pedestals comprising a thermally conductive material;
wherein the multi-layered membrane is supported by the support substrate such that the set of pedestals is aligned with the set of interleaved fingers.

20. The RF filter of claim 12, wherein the support substrate comprises one of SiC, diamond, BN, sapphire, and Si.
